(19) United States
(12) Patent Application Publication
(10) Pub. No.: US 2005/0121701 A1
(43) Pub. Date: Jun. 9, 2005

(54) Semiconductor device

(75) Inventors: Naohiko Hirano, Okazaki-city (JP); Shinji Amano, Kariya-city (JP); Rika Sakakibara, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/000,075

(22) Filed: Dec. 1, 2004

(30) Foreign Application Priority Data
Dec. 4, 2003 (JP) 2003-405911

(51) Int. Cl. H01L 29/80

(52) U.S. Cl. 257/287

(57) ABSTRACT

In a semiconductor device, risk of malfunction of a heat sensing diode on a main side of a vertical power semiconductor element is minimized by arranging the diode at the center of the element. Because the heat sensing diode is disposed at the center of the main side of the semiconductor element, the diode is protected from breakage and heat accumulation even when an excessive heat causes a crack at the periphery of a conductive bonding material that connects the element and the metal bodies on both sides of the element.

### CROSS REFERENCE TO RELATED APPLICATION

This application is based on and incorporates herein by reference Japanese Patent Application No. 2003-405911 filed on Dec. 4, 2003.

### FIELD OF THE INVENTION

The present invention relates to a semiconductor device that has a semiconductor element with a main electrode on each of its main side and its main reverse side. The semiconductor element has a first metal body on the main reverse side and second and third metal bodies on the main side, and also has a heat sensing diode for detecting temperature on the main side. The semiconductor device has a resin cover molded on it.

### BACKGROUND OF THE INVENTION

In FIG. 4A and FIG. 4B, a typical semiconductor device of this kind is shown schematically. The semiconductor device shown in FIG. 4A is proposed, for example, in US 2003/0022464 (JP-A-2003-110064).

In FIG. 4A, the semiconductor element 10 is, for example, a vertical power element such as an IGBT (Insulated Gate Bipolar Transistor), and its upside is a ‘main side’ that has an element disposed on it, and its downside is a ‘main reverse side.’

On the main side of the semiconductor element 10, a heat sensing diode 11 is disposed. The heat sensing diode 11 is a typical diode element that is manufactured using a material such as polysilicon or the like by a semiconductor manufacturing method. The heat sensing diode 11 changes its voltage depending on the temperature, and is used for detecting the temperature of the semiconductor element 10.

The semiconductor element 10 has a first metal body 20 as an electrode and a heatsink on its main reverse side attached electrically and thermally with a first conductive bonding material 51 such as a solder. Further, the semiconductor element 10, on its main side, has a second metal body 40 attached electrically and thermally with a second conductive bonding material 52 such as a solder.

Furthermore, the second metal body 40 has, on the side opposite to a semiconductor element 10 facing side, a third metal body 30 as an electrode and a heatsink attached electrically and thermally with a third conductive bonding material 53 such as a solder.

Various kinds of signal terminals 60 are disposed surrounding the semiconductor element 10, and the main side of the semiconductor element 10 and the signal terminals 60 are connected electrically by bonding wires 70. Most part of the surface of the semiconductor device is sealed with resin molding 80 in this case.

Among the five signal terminals 60 shown in FIG. 4A, two terminals on the right is for heat sensing diode 11, that is, terminals for heat detection, and the rest of the terminals are terminals connected electrically to signal electrodes of the semiconductor element 10 and base terminals.

However, the semiconductor device of this kind suffers from heat generation because of the density of implementation and the like. This situation leads to a possibility of crack in the second conductive bonding material 52 between the semiconductor element 10 and the second metal body 40 in FIG. 4A. This crack usually breaks out from the outer periphery of the second conductive bonding material 52. That is, the second conductive bonding material 52 exfoliates at the outmost periphery of the semiconductor element 10.

The above conventional semiconductor element 10 has the heat sensing diode 11 at its periphery on the main side. Therefore, the exfoliation of the second conductive bonding material 52 by a crack at the outmost periphery of the semiconductor element 10 causes a defective operation of the heat sensing diode 11. This is because the heat sensing diode 11 is disposed at the periphery of the semiconductor element 10, resulting in a breakage of the diode 11 from a concentrated stress of the crack.

Another cause of the defective operation of the heat sensing diode 11 is contributed to an interruption of a heat dissipation path caused by the crack in the second conductive bonding material 52 at the periphery of the semiconductor element 10. The interrupted heat dissipation path causes heat accumulation around the heat sensing diode 11 resulting in a defective operation.

### SUMMARY OF THE INVENTION

The present invention, in view of the above problems, devises a semiconductor device with a main electrode on each of the main side and the main reverse side of the semiconductor element having a first metal body on the main reverse side and a second/third metal body on the main side, and also having a heat sensing diode on the main side of the semiconductor element, most of the device covered by a molding material, such as a resin. The inventive structure of the semiconductor device prevents a defective operation of the heat sensing diode caused by a crack in the conductive bonding material between the main side of the semiconductor element and the second metal body.

In the present invention, a semiconductor device has a semiconductor element with a main electrode on each of a main side and a main reverse side. The semiconductor element has a heat sensing diode on the main side for detecting temperature. The semiconductor element has the following three parts on it, that is, a first metal body as an electrode and a heatsink attached to the main electrode on the main reverse side of the element with a first conductive bonding material, a second metal body attached to the main electrode on the main side of the semiconductor element with a second conductive bonding material, and a third metal body as an electrode and a heatsink attached to a side opposite to the semiconductor element facing side of the second metal body with a third conductive bonding material. In the semiconductor device molded for the most part by a molding material such as a resin, the heat sensing diode is disposed at the center of the main side of the semiconductor element.

Because of the arrangement of the heat sensing diode on the main side of the semiconductor element, a crack on the periphery of the second conductive bonding material does not affect the operation of the heat sensing diode, and thus the structure minimizes the risk of malfunction of the device.

The disposition location of the heat sensing diode can be described in the following ways on the main side of the semiconductor element. The location on the semiconductor element is defined as a square having the center point of the element inside, with one side being half the length of one side of the semiconductor element and the other side being half the length of the other side of the semiconductor element.

The location on the semiconductor element can also be defined as a area having a size of one fourth of the semiconductor element, with a base point existing on the center point of the semiconductor element.

The arrangement of cell blocks in a row on the semiconductor element is such that the heat sensing diode is located in between the two cell blocks at the center of the row when number of the blocks is even. The arrangement of cell blocks in a row on the semiconductor element can also be such that the heat sensing diode is located on either side of the center cell block of the row when number of the blocks is odd.

The first conductive bonding material, the second conductive bonding material, and the third conductive bonding material in the semiconductor device are a Sn (tin) solder. Further, the heat sensing diode and a lead of the heat sensing diode is covered by a protection cover of thickness of 2 μm or more made of polyimide on the main side of the semiconductor element in the semiconductor device.

The above-described structure appropriately provides a protection for the heat sensing diode and the lead of the heat sensing diode and an electrical insulation for them.

### BRIEF DESCRIPTION OF THE DRAWINGS

The above and other objects, features and advantages of the present invention will become more apparent from the following detailed description made with reference to the accompanying drawings. In the drawings:

FIGS. 1A and 1B are a schematic plan view and a schematic cross-sectional view illustrating a semiconductor device in the first embodiment of the present invention.

FIG. 2A shows a schematic plan view of a semiconductor element seen from a main side, and FIG. 2B shows a schematic cross-sectional view along the IIB-IIB line in FIG. 2A.

FIG. 3 shows a schematic plan view of a semiconductor element in the second embodiment of the present invention seen from a main side.

FIGS. 4A and 4B are a schematic plan view and a schematic cross-sectional view illustrating a conventional semiconductor device.

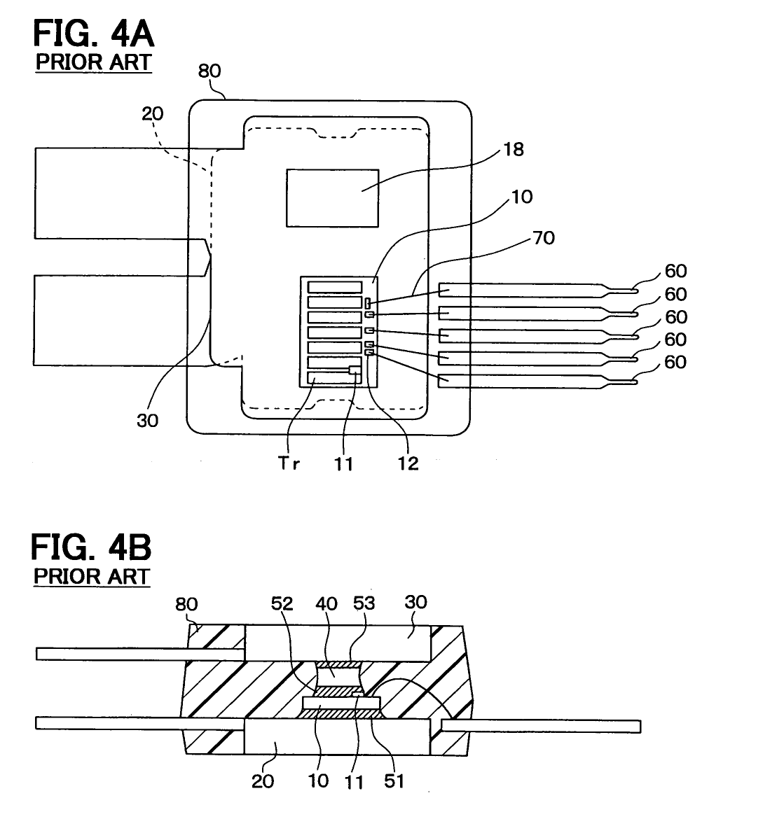

### DETAILED DESCRIPTION OF THE PREFERRED EMBODIMENT

The present invention will be described in detail with respect to a semiconductor device having a crack resistance capability in terms of a semiconductor element disposed on the device.

### First Embodiment

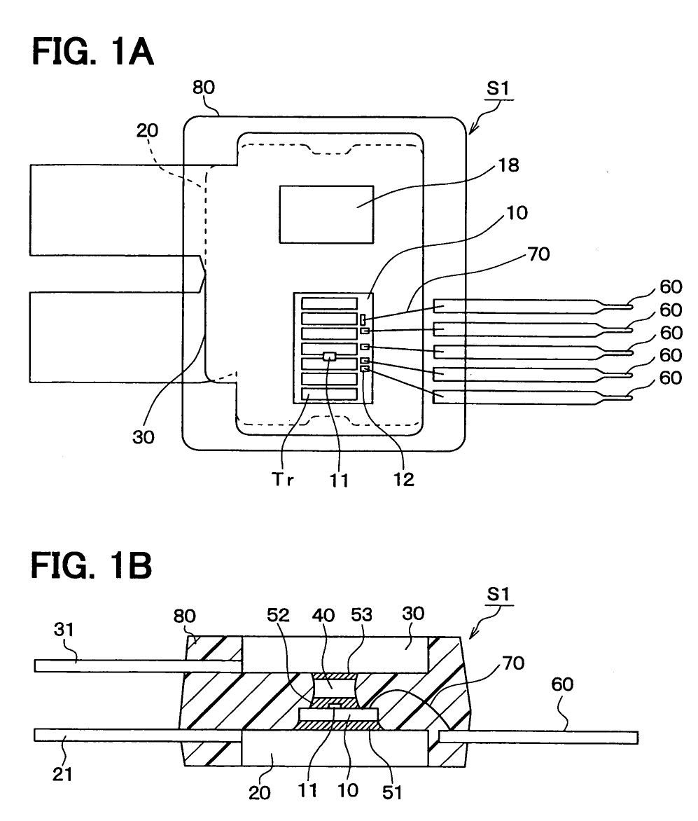

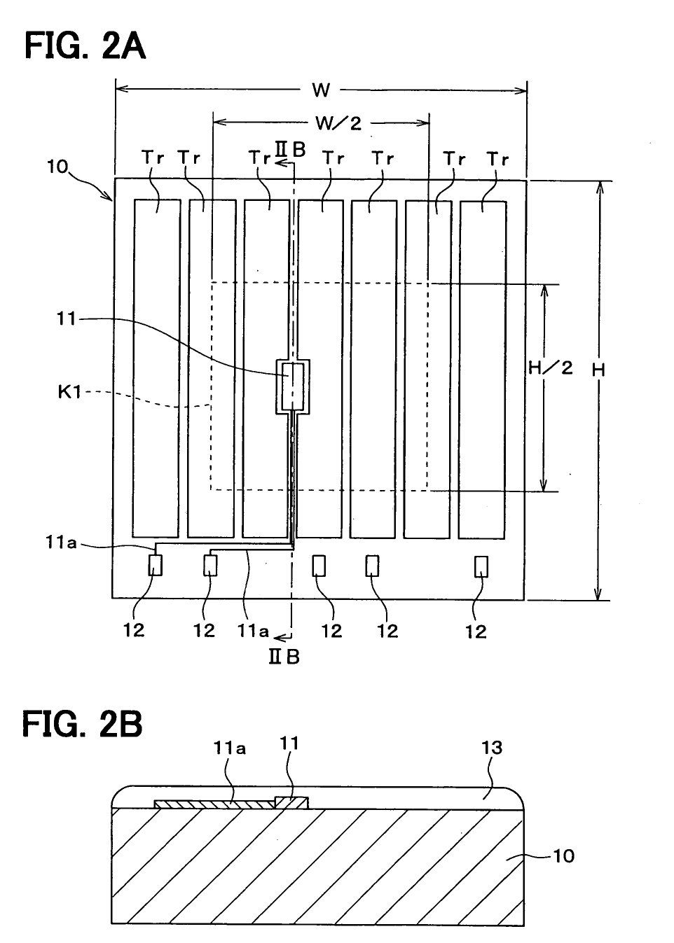

A semiconductor device S1 in the present embodiment, as shown in FIGS. 1A, 1B, 2A and 2B, comprises a first semiconductor chip 10 as a semiconductor element, a lower heatsink 20 as a first metal body, an upper heatsink 30 as a third metal body, a heatsink block 40 as a second metal body, conductive bonding materials 51, 52, 53 placed between the semiconductor element and the metal bodies, a heat sensing diode 11 disposed on the first semiconductor chip 10, and a resin mold 80.

In the present embodiment, the first semiconductor chip 10 is sided by a second semiconductor chip 18. In this structure, downsides of the semiconductor chips 10, 18 and an upside of the lower heatsink 20 are bonded by a first conductive bonding material 51. Further, upsides of the semiconductor chips 10, 18 and downsides of the heatsink blocks 40 are bonded by a second conductive bonding material 52. Furthermore, upsides of the heatsink blocks 40 and a downside of an upper heatsink 30 are bonded by a third conductive bonding material 53.

As the first, second, and third conductive bonding materials 51, 52, 53, a solder, conductive bonding materials or the like can be used. In the present embodiment, an Sn (tin) solder is used.

Heat dissipation is conducted through the second conductive bonding material 52, the heatsink block 40, the third conductive bonding material 53 and the upper heatsink 30 from the upsides of the first and second semiconductor chips 10, 18. Heat dissipation from the downside of the first and second semiconductor chips 10, 18 is conducted through the first conductive bonding material 51 and the lower heatsink 20.

As the first semiconductor chip 10, a power semiconductor element such as an IGBT (Insulated Gate Bipolar Transistor) or a thyristor is mainly, but not limitedly, used. As the second semiconductor chip 18, FWD (Free Wheel Diode) or the like is used.

A shape of the first semiconductor chip 10 is, for example, a thin board of rectangle. In FIG. 1B, the upside of the first semiconductor chip 10 is a main side where an element is disposed, and the downside is a main reverse side.

As shown in FIG. 2A, the main side of the first semiconductor chip 10 has an odd number (e.g. seven) of cell blocks Tr arranged in a row.

Each cell block Tr has a main electrode for the main side (not shown in FIGS.). The main reverse side of the first semiconductor chip 10 also has a main electrode (not shown in FIGS.).

The main electrode of the first semiconductor chip 10 can be, for example, an emitter for the main electrode on the main side, and a collector for the main electrode on the main reverse side.

As shown in FIG. 2A, the heat sensing diode 11 is disposed on the main side of the first semiconductor chip 10.

The heat sensing diode 11 is a typical diode element, manufactured using a material such as polysilicon or the like by a semiconductor manufacturing method. This element has a heat sensing capability as a changing voltage, and thus it is used for detecting the temperature of the first semiconductor chip 10.

As shown in FIG. 2A, the heat sensing diode 11 has two attached leads 11a. Each lead 11a is electrically connected to a pad 12 disposed at the periphery of the first semiconductor chip 10.

Also as shown in FIG. 2A, the heat sensing diode 11 is disposed at the center of the main side of the first semiconductor chip 10.

That is, the heat sensing diode 11 is disposed in the rectangular area K1 shown with a dotted line in FIG. 2A when the chip 10 has a rectangular board shape. In other words, the diode 11 is disposed within the area K1 from the center point of the main side, having a longitudinal side being half the length of longitudinal side of the first semiconductor chip 10, that is H/2, and a lateral side being half the length of lateral side of the chip 10, that is W/2.

The dotted line square K1 in FIG. 2A, in other words, has a longitudinal side of a length of H/2 and a lateral side of a length of W/2. The heat sensing diode 11 is disposed in this square area.

The heat sensing diode 11 is disposed in an area that occupies one fourth size of the main side surface area around the center point of the semiconductor chip 10, based on the relationship between each side of the square area K1 and each side of the first semiconductor chip 10.

Even when the first semiconductor chip 10 does not have a rectangular shape, the heat sensing diode 11 should be disposed in the area that occupies one fourth of the main side surface size around the center point of the semiconductor chip 10.

In this case, the heat sensing diode 11 is preferably on one side of the center cell block Tr of the seven cell blocks Tr. In that way, the heat sensing diode 11 is disposed appropriately in the center of the first semiconductor chip 10.

Though the heat sensing diode 11 is disposed on the left of the center cell block Tr, the diode 11 may be disposed on the right, or on both sides.

The heat sensing diode 11 and a lead 11a attached to the heat sensing diode 11 are covered with a protection cover 13 made of polyimide with thickness of 2 μm or more.

The main electrode on the main reverse side of the first semiconductor chip 10 is electrically connected to the lower heatsink 20 as the first metal body by the first conductive bonding material 51. The main electrode on the main side of the first semiconductor chip 10 is electrically connected to the heatsink block 40 as the second metal body by the second conductive bonding material 52.

Further, the heatsink block 40 is, on the side opposite to the semiconductor chips 10, 18, electrically connected to the upper heatsink 30 as the third metal body by the third conductive bonding material 53.

The lower heatsink 20, the upper heatsink 30, and the heatsink block 40 are made of, for example, a high heat/electrical conductivity such as a copper alloy, an aluminum alloy or the like. The heatsink block 40 may be made of a generic metal alloy.

The lower heatsink 20 is formed in a shape of, for example, rectangular board. A terminal 21 mounted on the lower heatsink 20 is used as an electrode for substrate mounting to be attached to the main electrode, that is a collector electrode for example, on the main reverse side of the semiconductor chip 10.

The heatsink block 40 is, for example, formed in a shape of rectangular board slightly smaller than the semiconductor chip 10.

The heatsink block 40 is disposed between the semiconductor chips 10, 18 and the upper heatsink 30 thermally and electrically connecting the chips 10, 18 and the heatsink 30. The heatsink block 40 also works as a spacer between the first semiconductor chip 10 and the upper heatsink 30 so that a sufficient height for a bonding wire 70 described later can securely be reserved between the chip 10 and the heatsink 30.

Further, the upper heatsink 30 is also formed in a shape of rectangular board as a whole. A terminal 31 mounted on the upper heatsink 30 is used as an electrode for substrate mounting to be attached to the main electrode, that is an emitter for example, on the main side of the semiconductor chip 10.

The terminal 21 of the lower heatsink 20 and the terminal 31 of the upper heatsink 30 are, as described above, the substrate mounting electrode connected to the main electrode of the semiconductor chip 10, that is, these terminals 21, 31 are disposed for a connection to a wiring outside of the semiconductor chip of the semiconductor device S1.

The lower heatsink 20 and the upper heatsink 30 are formed respectively as the first metal body and the third metal body, either of them being used as an electrode and a heatsink. That is, these metal bodies are used as electrodes of the semiconductor chip 10 in the semiconductor device S1 as well as heatsinks for dissipating heat from the semiconductor chips 10, 18.

A signal terminal 60 is disposed around the first semiconductor chip 10. This signal terminal 60 is used as a terminal and a base terminal electrically connected to a signal electrode (a gate electrode, for example) on the surface of the first semiconductor chip 10, the heat sensing diode 11 and the like.

Each signal terminal 60 is, for example, electrically connected by the wire 70 to a pad 12 disposed on the periphery of the first semiconductor chip 10, as shown in FIG. 1A. The wire 70 is formed by a wire bonding or the like, and is made of gold, aluminum or the like.

Each pad 12 is electrically connected to the heat sensing diode 11 or the signal electrode of the first semiconductor chip 10.

The five signal terminals 60 are electrically connected to the pads 12 by the wire 70. The lower two terminals, for example, are used as temperature detection terminals connected to the heat sensing diode 11, and the rest are used as the terminals electrically connected to the signal electrodes on the semiconductor chip 10 and the base terminals.

The above components such as terminals 60, pads 12 and bonding wires 70 are sealed and molded almost entirely by a resin 80. That is, as shown in FIG. 1B, a space between a pair of heatsinks 20, 30, and a surrounding area of the semiconductor chips 10, 18 and the heatsink block 40, are filled and sealed with the resin 80.

As the material of the resin 80, a normal mold material such as an epoxy resin and the like may be used. Molding for the heatsinks 20, 30 and the like is easily formed by a form block with an upper and lower molds (not shown in FIGS.) in a transfer mold method.

The semiconductor device S1 is basically formed as a resin mold semiconductor device with the first semiconductor chip 10 as a vertical power element having electrically and thermally connected metal bodies 20, 30, 40 on both sides and the heat sensing diode 11 on the main side of the semiconductor chip 10.

Manufacturing method of the semiconductor device S1 is described with reference to FIG. 1A and FIG. 1B. A process for soldering the upsides of the lower heatsink 20 with the semiconductor chips 10, 18 and the heatsink blocks 40 comes first.

In this case, the semiconductor chips 10, 18 are layered with, for example, a Sn solder foil on the upside of the lower heatsink 20, and the heatsink blocks 40 are layer on the semiconductor chips 10, 18 with the same solder foil.

The solder foil is melted by a heating device (a reflow device) to a temperature above a melting point of the solder, and the melted solder is then hardened.

A process for wire-bonding the first semiconductor chip 10 and the signal terminal 60 is conducted. The semiconductor chip 10 and the signal terminal 60 are electrically connected by the wire 70.

A process for soldering the upper heatsink 30 on each of the heatsink blocks 40 is conducted. In this process, the upper heatsink 30 is placed with a solder foil on the heatsink blocks 40. The solder foil is melted by the heating device and then hardened.

The hardened solder foils are formed as the first, the second, and the third conductive bonding materials 51, 52, 53.

These processes complete the electrical and thermal connection between the lower heatsink 20, the semiconductor chips 10, 18, heatsink blocks 40, and the upper heatsink 30 beside physical connection by the conductive bonding materials 51, 52, 53.

When a conductive adhesive is used as the first, second, and third conductive bonding material 51, 52, 53, the processes described above are utilized to achieve a physical, an electrical and a thermal connection between the lower heatsink 20, the semiconductor chips 10, 18, the heatsink blocks 40 and the upper heatsink 30 by replacing the solder with the conductive adhesive and by replacing placement of the solder foil with application and hardening of the conductive adhesive.

A process for filling the resin 80 into a space between the heatsinks 20, 30 and other peripheral portion by using a form block (not shown in FIGS.) is then conducted. The resin 80 fills the space such as the space between the heatsink 20 and 30, the peripheral portion and the like, in the process.

Manufacturing process of the semiconductor device S1 completes when the device S1 is taken out of the form block after the resin 80 is hardened.

The downside of the lower heatsink 20 and the upside of the upper heatsink 30 are exposed from the resin mold . This contributes to an increased heat dissipation capacity of the heatsinks 20, 30.

In the present embodiment, the semiconductor device S1 has a semiconductor element 10 with a main electrode on each of a main side and a main reverse side, having a heat sensing diode 11 on the main side for detecting temperature, the lower heatsink 20 attached to the main electrode on the main reverse side of the semiconductor element 10 with the first conductive bonding material 51, the heatsink blocks 40 attached to the main electrode on the main side of the semiconductor element 10 with a second conductive bonding material 52, and the upper heatsink 30 attach to a side opposite to the semiconductor element 10 facing side of the heatsink blocks 40 with a third conductive bonding material 53, and the semiconductor device S1 is provided with the heat sensing diode 11 disposed at the center of the main side of the semiconductor element 10, covered almost entirely by the resin 80.

According to the above embodiment, the heat sensing diode 11 disposed at the center of the main side of the first semiconductor chip 10 is not close to a position of a crack, when the crack breaks on the periphery of the second conductive bonding material 52. Therefore, the heat sensing diode 11 will not severely be affected by the crack, that is, concentration of stress from the crack to the heat sensing diode 11, an interruption of heat dissipation path by a exfoliation of the second conductive bonding material 52, and the like.

Risk of malfunction of the heat sensing diode 11 is, thus, minimized, even when a crack breaks out in the conductive bonding material 52 that connects the main side of the first semiconductor chip 10 and the heatsink block 40 as the second metal body.

As a result, the semiconductor device can stably conduct a high temperature protection control by appropriately detecting the maximum temperature of the first semiconductor chip 10.

The area for the heat sensing diode 11 disposition at the center of the first semiconductor chip 10 is preferably the area shown in FIG. 2A.

That is, the heat sensing diode 11 on the first semiconductor chip 10 is preferably disposed from the center point of the main side within an area having half the length H/2 of longitudinal side and half the length W/2 of lateral side, when the first semiconductor chip 10 has a shape of rectangular board.

The heat sensing diode 11 on the first semiconductor chip 10 is preferably disposed from the center point of the main side within an area K1 having the size of one fourth of the main side without regard to the shape of the first semiconductor chip 10.

The heat sensing diode 11 on the first semiconductor chip 10 is preferably disposed on at least one side of the center cell block Tr, as shown in FIG. 2A, when multiple cell blocks Tr are arranged in a row and the number of the cell blocks Tr is odd.

The heat sensing diode 11 and the lead 11a attached to the heat sensing diode 11 on the first semiconductor chip 10, as shown in FIG. 2B, are covered by the protection cover 13 having thickness of 2 μm or more made of polyimide.

The above-described structure is preferred, because the heat sensing diode 11 and the lead 11a attached to the heat sensing diode 11 is appropriately protected and insulated.

### Second Embodiment

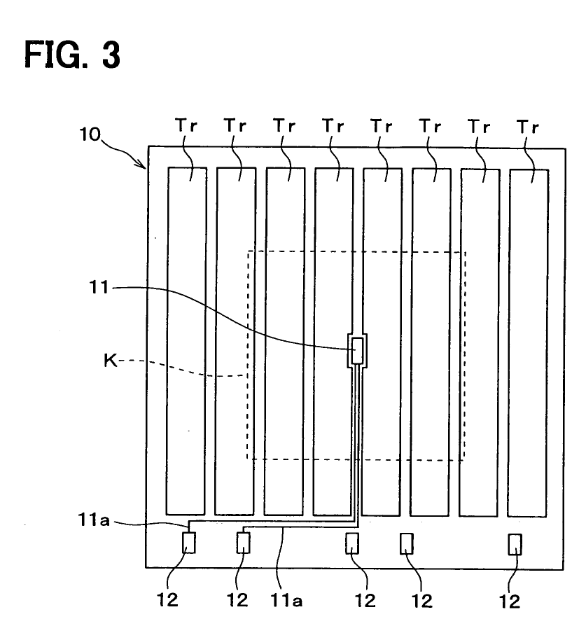

In this embodiment shown in FIG. 3, the multiple cell blocks Tr are arranged in a row on the main side of the first semiconductor chip 10. The number of the cell block Tr is even (e.g. eight).

In this case, the heat sensing diode 11 is disposed between the two cell blocks Tr at the center in the row. According to this arrangement, the heat sensing diode 11 can appropriately be disposed at the center of the main side on the first semiconductor chip 10.

Except for the difference described above, the semiconductor device in this embodiment provides the same operational effect as in the first embodiment.

### Other Embodiments

The semiconductor element used for this invention is not limited to the power semiconductor element such as an IGBT, a thyristor, and the like, but a semiconductor element with a main electrode on a main side and a main reverse side.

1. A semiconductor device almost entirely molded by a molding material comprising:
a semiconductor element having a heat sensing diode for detecting temperature on a main side, and a main electrode on each of the main side and a main reverse side of the semiconductor element;
a first metal body attached to the main electrode on the main reverse side of the semiconductor element with a first conductive bonding material as an electrode and a heatsink;
a second metal body attached to the main electrode on the main side of the semiconductor element with a second conductive bonding material; and
a third metal body attached to a side opposite to the semiconductor element facing side of the second metal body with a third conductive bonding material as an electrode and a heatsink,
wherein the heat sensing diode is disposed at the center of the main side of the semiconductor element.

2. The semiconductor device of claim 1, wherein:
the semiconductor element has a rectangular board shape; and
the heat sensing diode is disposed inside a rectangular area having two sides that are of half the length of the longitudinal side of the semiconductor element and of half the length of the lateral side of the semiconductor element, at the center of the main side of the semiconductor element.

3. The semiconductor device of claim 1,
wherein the heat sensing diode is disposed in an area having one fourth of the total size of the main side of the semiconductor element located at the center of the main side of the semiconductor element.

4. The semiconductor device of claim 2, wherein:
the semiconductor element has multiple cell blocks arranged in a row on the main side;
the number of the cell blocks is even; and
the heat sensing diode is disposed between the two adjacent cell blocks at the center of the row.

5. The semiconductor device of claim 2, wherein:
the semiconductor element has multiple cell blocks arranged in a row on the main side;
the number of the cell block is odd; and
the heat sensing diode is disposed at least on one side of the center cell block in the row.

6. The semiconductor device of claim 1,
wherein the first conductive bonding material, the second conductive bonding material, and the third conductive bonding material are made of a tin solder.

7. The semiconductor device of claim 1,
wherein the heat sensing diode and a lead attached to the diode are covered by a protection cover of polyimide of thickness of 2 μm or more.
